(19) United States
(12) Patent Application Publication
(10) Pub. No.: US 2018/0372507 A1
(43) Pub. Date: Dec. 27, 2018

(54) INFORMATION SHARING METHOD OF SMART ELECTRICITY METER, SMART ELECTRICITY METER AND ACQUISITION ROUTER

(71) Applicants: CHINA ELECTRIC POWER RESEARCH INSTITUTE COMPANY LIMITED, Beijing (CN); STATE GRID CORPORATION OF CHINA, Beijing (CN); XJ GOURP CORPORATION, Xuchang (CN)

(72) Inventors: Wenpeng Luan, Beijing (CN); Biao He, Beijing (CN); Fengquan Zhou, Beijing (CN); Peng Wang, Beijing (CN); Daqing Xu, Beijing (CN); Zhanguo Zhang, Beijing (CN); Xuezheng Xie, Beijing (CN)

(21) Appl. No.: 15/742,881

(22) PCT Filed: Jul. 11, 2016
(86) PCT No.: PCT/CN2016/089697

§ 371 Date: Jan. 8, 2018

(30) Foreign Application Priority Data
Jul. 9, 2015 (CN) 201510400576.1

(51) Int. Cl. G01D 4/00; G01R 19/25; G01R 21/133; H04L 29/08; H04L 29/06

(52) U.S. Cl. CPC G01D 4/004; G01R 19/2513; H04L 69/16; H04L 29/08036; G01R 21/1333

(57) ABSTRACT

An information sharing method for a smart electricity meter, the smart electricity meter and an acquisition router are provided. Multiple Internet Protocol version 6 (IPv6) addresses are allocated to the smart electricity meter; the smart electricity meter specifies the corresponding IPv6 address according to a type of information to initiate a Transmission Control Protocol (TCP)/Internet Protocol (IP) connection to the acquisition router; and the acquisition router searches for routing IPv6 addresses with same rules as rules of the IPv6 address according to the IPv6 address, and sends the information to destination addresses specified by the information through the routing IPv6 addresses.

### TECHNICAL FIELD

The disclosure relates to the field of information distribution and sharing of a smart electricity meter, and particularly to an information sharing method for a smart electricity meter, a smart electricity meter and an acquisition router.

### BACKGROUND

A smart electricity meter is key equipment of a smart grid. Compared with a conventional electricity meter, the smart electricity meter has a powerful communication capability and a function of recording detailed load information of a user, besides an electric energy metering function. The smart electricity meter may obtain multiple measurements (for example, an electricity consumption, an electricity demand, a voltage, a current and power) with time stamps for the user, and own network status and event information of the smart electricity meter. This information may be widely applied to each related service master station system of a power distribution network. For example, a capacitor is built-in the smart electricity meter, such that “power loss” failure information (Last gasp) may still be reported to an outage management system even after a power failure of a line. A failure range may be clearly determined from failure information received from each smart electricity meter, and if the smart electricity meters are combined with a geographic information system, a correlation of each failure point may further be displayed through a distribution and topological relationship of the failure points. In addition, the network status information may be used in a network management master station system for rapidly detecting an operation status of each unit in the network and a network failure. Electricity consumption information of the smart electricity meter is used in a metering data collection and management system to realize a billing function. Load information such as the voltage and the current may assist in status assessment of power distribution automation and the like.

In each master station system of an existing power distribution network, information of a smart electricity meter is interrogated, acquired, parsed, distributed and shared through an electricity consumption information acquisition master station system. After connection is established with a front end service module of the electricity consumption information acquisition master station system and successful login, the smart electricity meter packs various kinds of information into a complete message and transmits it to the front end service module, and the front end service module parses the message according to the “Power User Electric Energy Data Acquisition System Communication Protocol” specified by power companies, acquires an Average Failure Number (AFN) control word in the information message of the smart electricity meter, and distributes and shares the information to another related master station system of the power distribution network according to a type of the AFN control word for implementing each specific service. However, multiple intermediate links for data exchange between service systems and message parsing of the front end service module increase a system resource consumption and also weaken a system access capability.

Therefore, how to design an information sharing method for the smart electricity meter to improve speed and reliability of information distribution and sharing and simultaneously simplify the front end service module of the electricity consumption information acquisition master station system is a problem urgent to be solved in this field.

### SUMMARY

In view of this, the disclosure provides an information sharing method for a smart electricity meter, a smart electricity meter and an acquisition router. The method, the smart electricity meter and the acquisition router achieve peer-to-peer communication and data transmission between each service master station system and the smart electricity meter, improve speed and reliability of information distribution and sharing, enable each master station system of a power distribution network to process information more smartly and reasonably, simplify a front end service module of an electricity consumption information acquisition master station system, reduce a system resource consumption, improve a system access capability and ensure stable and efficient operation of a smart grid.

The purpose of the disclosure is achieved by the following technical solutions.

An information sharing method for a smart electricity meter is provided, information sharing of the smart electricity meter occurring in an electricity consumption information acquisition master station system in a power distribution network, the method including that:

multiple Internet Protocol version 6 (IPv6) addresses are allocated to the smart electricity meter, wherein each of the IPv6 addresses is configured to send and receive information of a respective type;

the smart electricity meter specifies an IPv6 address corresponding to a type of the information to initiate a Transmission Control Protocol (TCP)/Internet Protocol (IP) connection to an acquisition router; and

the acquisition router searches for routing IPv6 addresses with same rules as rules of the IPv6 address according to the IPv6 address, and sends the information to destination addresses specified by the information through the searched out routing IPv6 addresses.

Preferably, before the operation that the multiple IPv6 addresses are allocated to the smart electricity meter, the method includes that:

the smart electricity meter receives the information from the electricity consumption information acquisition master station system, the information including measurements with time stamps for a user and own network status and event information of the smart electricity meter, and

the measurements including an electricity consumption, an electricity demand, a voltage, a current and a power.

Preferably, before the operation that the smart electricity meter specifies the IPv6 address corresponding to the type of the information to initiate the TCP/IP connection to the acquisition router, the method includes that:

the smart electricity meter receives a command for acquiring the information, the command for acquiring the information being sent by a system in a metering data collection and management system, a power distribution automation management system, an outage management system or the electricity consumption information acquisition master station system.

Preferably, before the operation that the smart electricity meter specifies the IPv6 address corresponding to the type of the information to initiate the TCP/IP connection to the acquisition router, the method includes that:

the smart electricity meter reaches a preset time for actively reporting the information.

Preferably, the operation that the acquisition router searches for the routing IPv6 addresses with the same rules as the rules of the IPv6 address according to the IPv6 address, and sends the information to the destination addresses specified by the information through the searched out routing IPv6 addresses includes that:

the acquisition router determines priorities of a plurality of pieces of information according to Quality of Service (QOS) rules, and when the acquisition router simultaneously receives multiple TCP/IP connections initiated by the smart electricity meter,

for each of the plurality of pieces of information, the acquisition router searches for the routing IPv6 addresses with the same rules as the rules of the IPv6 address corresponding to the piece of information in sequence according to the priority of the piece of information; and

the acquisition router sends the piece of information to destination addresses specified by the piece of information through the searched out routing IPv6 addresses according to the priority of the piece of information.

A smart electricity meter is provided, which includes an IPv6 address module, an information data receiving module and an information data sending module, wherein

the IPv6 address module is configured to create, receive and store IPv6 addresses allocated to the smart electricity meter, each of the IPv6 addresses being configured to send and receive information of a respective type;

the information data receiving module is configured to, in an electricity consumption information acquisition master station system, acquire, receive and store measurements with time stamps for a user and own network status and event information of the smart electricity meter, the measurements including an electricity consumption, an electricity demand, a voltage, a current and a power; and

the information data sending module is configured to extract an IPv6 address corresponding to information from the information data receiving module according to a type of the information, and initiate a TCP/IP connection to an acquisition router.

Preferably, the smart electricity meter further includes a command receiving module; and

the command receiving module is configured to receive a command for acquiring the information, the command for acquiring the information being sent by a system in a metering data collection and management system, a power distribution automation management system, an outage management system or the electricity consumption information acquisition master station system.

Preferably, the smart electricity meter further includes a timing module; and

the timing module is configured to set a time at which the information is actively reported by the smart electricity meter, and when preset time for actively reporting the information is reached, send an information sending command to the information data sending module.

An acquisition router is provided, which includes a receiving module, a routing IPv6 address module and a sending module, wherein

the receiving module is configured to receive a TCP/IP connection initiated by a smart electricity meter;

the routing IPv6 address module is configured to store routing IPv6 addresses, and search for the routing IPv6 addresses with same rules as rules of an IPv6 address according to the IPv6 address; and

the sending module is configured to send information to destination addresses specified by the information through the searched out routing IPv6 addresses.

Preferably, the acquisition router further includes a prioritizing module;

the prioritizing module is configured to determine priorities of a plurality of pieces of information according to QOS rules;

when the acquisition router simultaneously receives multiple TCP/IP connections initiated by the smart electricity meter,

for each of the plurality of pieces of information, the prioritizing module is configured to control the acquisition router to search for the routing IPv6 addresses with the same rules as the rules of the IPv6 address corresponding to the piece of information in sequence according to the priority of the piece of information; and

the prioritizing module is configured to control the acquisition router to send the piece of information to destination addresses specified by the piece of information through the searched out routing IPv6 addresses according to the priority of the piece of information.

From the technical solutions described above, it can be seen that the embodiments of the disclosure provide the information sharing method for the smart electricity meter, the smart electricity meter and the acquisition router. The multiple IPv6 addresses are allocated to the smart electricity meter; the smart electricity meter specifies the IPv6 address corresponding to the type of the information to initiate the TCP/IP connection to the acquisition router; and the acquisition router searches for the routing IPv6 addresses with the same rules as the rules of the IPv6 address according to the IPv6 address, and sends the information to destination addresses specified by the information through the searched out routing IPv6 addresses. The information sharing method, smart electricity meter and acquisition router disclosed by the disclosure implement peer-to-peer communication and data transmission between each service master station system and the smart electricity meter, improve the speed and reliability of information distribution and sharing, enable each master station system of the power distribution network to process information more smartly and reasonably, simplify the front end service module of the electricity consumption information acquisition master station system, reduce the system resource consumption, improve the system access capability and ensure stable and efficient operation of the smart grid.

Compared with a closest prior art, the technical solutions provided by the embodiments of the disclosure have the following beneficial effects.

1: in the technical solutions provided by the embodiment of the disclosure, the multiple IPv6 addresses are allocated to the smart electricity meter; the smart electricity meter specifies the IPv6 address corresponding to the type of the information to initiate the TCP/IP connection to the acquisition router; and the acquisition router searches for the routing IPv6 addresses with the same rules as the rules of the IPv6 address according to the IPv6 address, and sends the information to the destination addresses specified by the information through the searched out routing IPv6 addresses. The information sharing method disclosed by the disclosure implements peer-to-peer communication and data transmission between each service master station system and the smart electricity meter, improves the speed and reliability of the information distribution and sharing, enables each master station system of the power distribution network to process information more smartly and reasonably, simplifies the front end service module of the electricity consumption information acquisition master station system, reduces the system resource consumption, improves the system access capability and ensures stable and efficient operation of the smart grid.

2: compared with an existing electricity consumption information acquisition master station system implementing parsing, distribution and sharing of the information of the smart electricity meter in an application layer of an Open System Interconnect (OSI) system model, the method disclosed in the disclosure is that in a network layer of the OSI system model, the types of the information is distinguished according to characteristics of the IPv6 addresses, and the information is directly distributed and shared to each related master station system. In other words, the acquisition router recognizes the characteristics of the IPv6 address of the smart electricity meter to determine the type of the information sent by the smart electricity meter, acquires a corresponding address set of master station systems, and forwards the information to each master station system. Therefore, peer-to-peer communication and data transmission between each service master station system and the smart electricity meter are implemented, intermediate links for data exchange between various service systems are reduced, and the speed and reliability of information distribution and sharing are improved.

3: according to the technical solutions provided by the embodiments of the disclosure, the information is classified by adopting multiple IPv6 addresses, such that the messages need not be parsed by the front end service module of the electricity consumption information acquisition master station system. Thus, the front end service module is simplified, the system resource consumption is reduced, and the system access capability is improved.

4: according to the technical solutions provided by the embodiments of the disclosure, the priorities are set in the information of the smart electricity meter, and network resources are preferably occupied to distribute and share the information with high priority to the respective master station systems to implement related services. The setting of the priorities enables each master station system of the power distribution network to process the information more smartly, allocate the network resources more reasonably and ensure preferred processing of important information of the smart electricity meter.

5: the technical solutions provided by the embodiments of the disclosure are widely applied, and have remarkable social benefits and economic benefits.

### BRIEF DESCRIPTION OF DRAWINGS

FIG. 1 is a flowchart of an embodiment of an information sharing method for a smart electricity meter according to the disclosure.

FIG. 2 is a structure diagram of a smart electricity meter according to the disclosure.

FIG. 3 is a structure diagram of an acquisition router according to the disclosure.

FIG. 4 is a schematic diagram of an application example of an information sharing method for a smart electricity meter according to the disclosure.

### DETAILED DESCRIPTION

The technical solutions in embodiments of the disclosure will be clearly and completely described below in combination with the drawings in the embodiments of the disclosure. Obviously, the described embodiments are not all embodiments but only part of embodiments of the disclosure. All other embodiments obtained by those skilled in the art on the basis of the embodiments of the disclosure without creative work fall within the scope of protection of the disclosure.

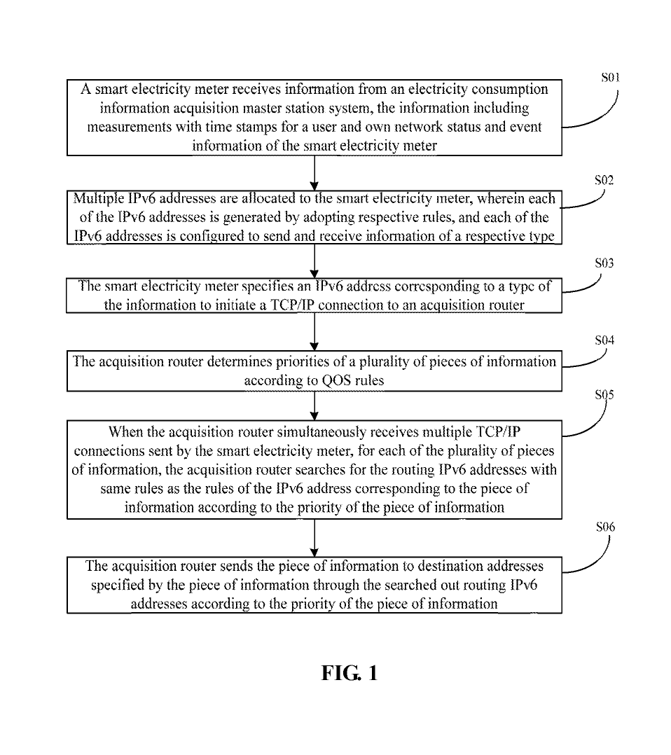

As shown in FIG. 1, the disclosure provides an information sharing method for a smart electricity meter, which is applied to an electricity consumption information acquisition master station system in a power distribution network. The method includes the following steps.

In S01, the smart electricity meter receives information from the electricity consumption information acquisition master station system, wherein the information includes: measurements with time stamps for a user and own network status and event information of the smart electricity meter, and wherein the measurements include: an electricity consumption, an electricity demand, a voltage, a current and a power.

In S02, at least one IPv6 address is allocated to the smart electricity meter, wherein each IPv6 address is generated by adopting different rules, and each IPv6 address is configured to send and receive information of a respective type.

In S03, the smart electricity meter determines the corresponding IPv6 address according to a type of the information, and initiates a TCP/IP connection to an acquisition router through the IPv6 address.

In S04, the acquisition router determines priorities of a plurality of pieces of information according to QOS rules.

In S05, when the acquisition router simultaneously receives multiple TCP/IP connections initiated by the smart electricity meter, for each of the plurality of pieces of information, the acquisition router searches for routing IPv6 addresses with same rules as the rules of the IPv6 address corresponding to the piece of information in sequence according to the priority of the piece of information.

In S06, the acquisition router sends the piece of information to destination addresses specified by the piece of information through the routing IPv6 addresses according to the priority of the piece of information.

Before the operation that the smart electricity meter determines the corresponding IPv6 addresses according to the type of the information and initiates the TCP/IP connection to the acquisition router, the method includes the following step.

The smart electricity meter receives a command for acquiring the information, the command for acquiring the information being sent by a system in a metering data collection and management system, a power distribution automation management system, an outage management system or the electricity consumption information acquisition master station system.

Or the method includes the following step.

The smart electricity meter reaches a preset time for actively reporting the information.

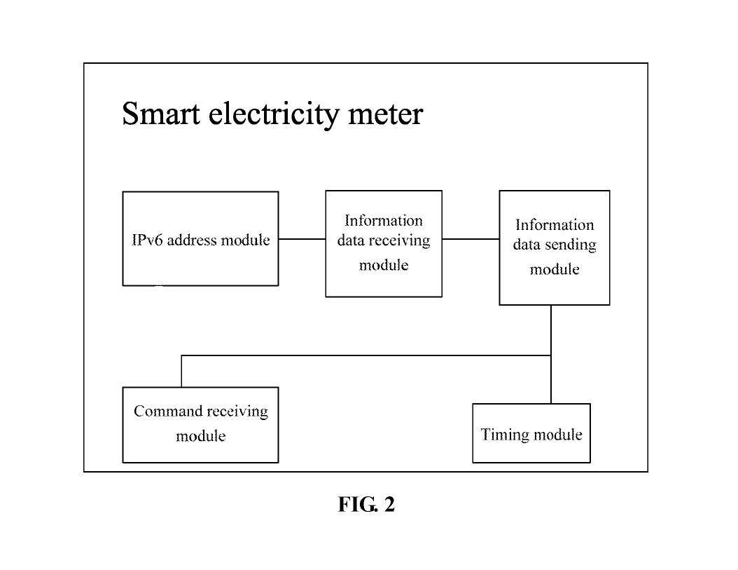

As shown in FIG. 2, the disclosure provides a smart electricity meter, which includes an IPv6 address module, an information data receiving module and an information data sending module.

The IPv6 address module is configured to create, receive and store IPv6 addresses allocated to the smart electricity meter, each of the IPv6 addresses being generated by adopting different rules and each of the IPv6 addresses being configured to send and receive information of a respective type.

The information data receiving module is configured to, in the electricity consumption information acquisition master station system, acquire, receive and store measurements with time stamps for a user and own network status and event information of the smart electricity meter, the measurements including an electricity consumption, an electricity demand, a voltage, a current and a power.

The information data sending module is configured to extract the IPv6 address corresponding to information from the information data receiving module according to a type of the information, and initiate a TCP/IP connection to an acquisition router.

The smart electricity meter further includes a command receiving module.

The command receiving module is configured to receive a command for acquiring the information, the command for acquiring the information being sent by a system in a metering data collection and management system, a power distribution automation management system, an outage management system or the electricity consumption information acquisition master station system.

The smart electricity meter further includes a timing module.

The timing module is configured to set a time at which the information is actively reported by the smart electricity meter, and when preset time for actively reporting information is reached, send an information sending command to the information data sending module.

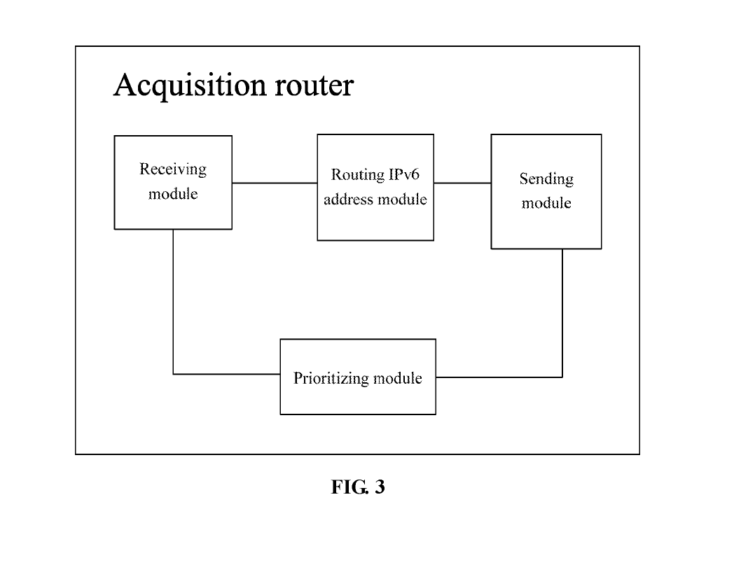

As shown in FIG. 3, the disclosure provides an acquisition router, which includes a receiving module, a routing IPv6 address module and a sending module.

The receiving module is configured to receive a TCP/IP connection initiated by a smart electricity meter.

The routing IPv6 address module is configured to store routing IPv6 addresses, and search for the routing IPv6 addresses with same rules as rules of an IPv6 address according to the IPv6 address.

The sending module is configured to send information to destination addresses specified by the information through the searched out routing IPv6 addresses.

The acquisition router further includes a prioritizing module.

The prioritizing module is configured to determine priorities of a plurality of pieces of information according to QOS rules.

When the acquisition router simultaneously receives multiple TCP/IP connections initiated by the smart electricity meter,

for each of the plurality of pieces of information, the prioritizing module is configured to control the acquisition router to search for the routing IPv6 addresses with the same rules as the rules of the IPv6 address corresponding to the piece of information in sequence according to the priority of the piece of information.

The prioritizing module is configured to control the acquisition router to send the piece of information to destination addresses specified by the piece of information through the searched out routing IPv6 addresses according to the priority of the piece of information.

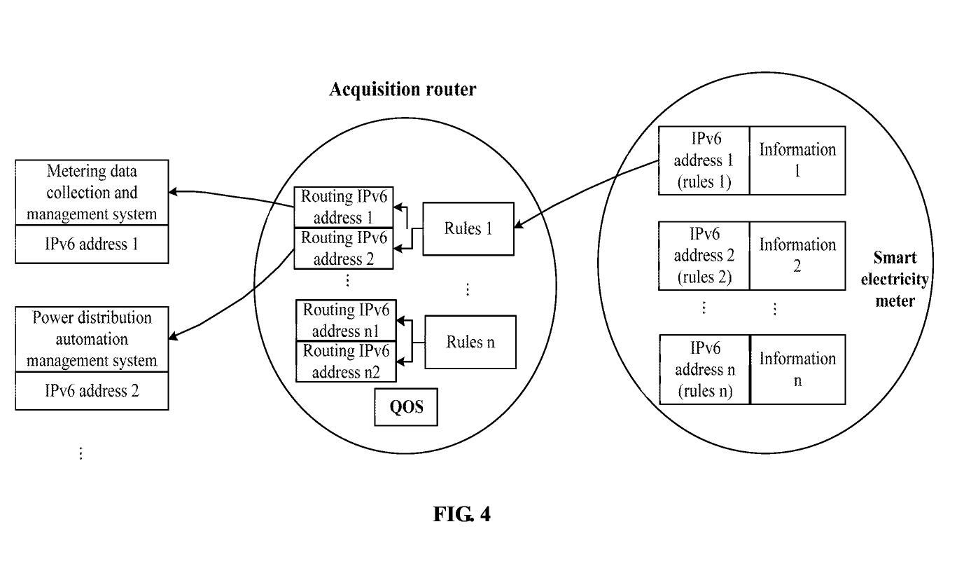

As shown in FIG. 4, the disclosure provides an application example of the information sharing method for the smart electricity meter. For example, there are n pieces of information in the smart electricity meter, and the smart electricity meter sends information 1 to the metering data collection and management system and power distribution automation management system in the master station system through the acquisition router, the method includes the following steps.

On the smart electricity meter, multiple IPv6 addresses are configured according to types of stored information, the information 1 being sent and received by adopting an IPv6 address 1 generated with rules 1 and information 2 being sent and received by adopting an IPv6 address 2 generated with rules 2.

A routing rule of the acquisition router is set as follows: after receiving a data packet with an IPv6 address meeting the “rules 1”, the data packet is forwarded to a “destination address 1” of the metering data collection and management system and a “destination address 2” of the power distribution automation management system through routing IPv6 addresses.

A QOS rule of the acquisition router is set as follows: priorities of the information of the smart electricity meter are judged according to the IPv6 addresses of the smart electricity meter, and the information with high priority is preferably processed.

After receiving an interrogation command or reaching a preset time for actively reporting the information, the smart electricity meter reports all types of stored information through respective IPv6 address: the smart electricity meter initiates a TCP/IP connection at first and starts a smart electricity meter information uploading process; the smart electricity meter sends a data packet to the superior acquisition router; and after receiving the data packet uploaded by the smart electricity meter, the acquisition router forwards the data packet of the smart electricity meter to the “destination address 1” of the metering data collection and management system and the “destination address 2” of the power distribution automation management system according to a setting of the routing rule.

When the acquisition router simultaneously receives multiple pieces of smart electricity meter information, the acquisition router preferably processes smart electricity meter information with high priority according to the configured QOS rule, and distributes and shares the smart electricity meter information to the corresponding master station systems.

The above embodiments are adopted not to limit but only to describe the technical solutions of the disclosure. Although the disclosure has been described in detail in the embodiments, those skilled in the art may still make modifications or equivalent replacements to specific implementation modes of the disclosure. Any modifications or equivalent replacements made without departing from the spirit and scope of the disclosure fall within the scope of protection of the claims of the disclosure.

1. An information sharing method for a smart electricity meter, applied to an electricity consumption information acquisition master station system in a power distribution network, the method comprising:
allocating at least one Internet Protocol version 6 (IPv6) address to the smart electricity meter, wherein each IPv6 address is configured to send and receive information of a respective type;
specifying, by the smart electricity meter, an IPv6 address corresponding to a type of the information to initiate a Transmission Control Protocol (TCP)/Internet Protocol (IP) connection to an acquisition router; and
searching, by the acquisition router, for routing IPv6 addresses with same rules as rules of the specified IPv6 address according to the specified IPv6 address, and sending the information to destination addresses specified by the information through the searched out routing IPv6 addresses.

2. The method according to claim 1, further comprising:
before allocating at least one IPv6 address to the smart electricity meter,
receiving, by the smart electricity meter, the information from the electricity consumption information acquisition master station system, the information comprising measurements with time stamps for a user and own network status and event information of the smart electricity meter,
wherein the measurements comprise an electricity consumption, an electricity demand, a voltage, a current and a power.

3. The method according to claim 1, further comprising:
before specifying, by the smart electricity meter, the IPv6 address corresponding to the type of the information to initiate the TCP/IP connection to the acquisition router,
receiving, by the smart electricity meter, a command for acquiring the information, the command for acquiring the information being sent by a system in a metering data collection and management system, a power distribution automation management system, an outage management system or the electricity consumption information acquisition master station system.

4. The method according to claim 1, further comprising:
before specifying, by the smart electricity meter, the IPv6 address corresponding to the type of the information to initiate the TCP/IP connection to the acquisition router,
reaching, by the smart electricity meter, a preset time for actively reporting the information.

5. The method according to claim 1, wherein searching, by the acquisition router, for the routing IPv6 addresses with the same rules as the rules of the specified IPv6 address according to the specified IPv6 address, and sending the information to the destination addresses specified by the information through the searched out routing IPv6 addresses comprises:
determining, by the acquisition router, when the acquisition router simultaneously receives a plurality of TCP/IP connections initiated by the smart electricity meter, priorities of a plurality of pieces of information according to Quality of Service (QOS) rules, and
for each of the plurality of pieces of information, searching, by the acquisition router, for the routing IPv6 addresses with the same rules as the rules of the IPv6 address corresponding to the piece of information in sequence according to the priority of the piece of information; and
sending, by the acquisition router, the piece of information to destination addresses specified by the piece of information through the searched out routing IPv6 addresses according to the priority of the piece of information.

6. A smart electricity meter, comprising an Internet Protocol version 6 (IPv6) address device, an information data receiver and an information data sender, wherein
the IPv6 address device is configured to create, receive and store IPv6 addresses allocated to the smart electricity meter, each of the IPv6 addresses being configured to send and receive information of a respective type;
the information data receiver is configured to, in an electricity consumption information acquisition master station system, acquire, receive and store measurements with time stamps for a user and own network status and event information of the smart electricity meter, the measurements comprising an electricity consumption, an electricity demand, a voltage, a current and a power; and
the information data sender is configured to extract an IPv6 address corresponding to information from the information data receiver according to a type of the information, and initiate a Transmission Control Protocol (TCP)/Internet Protocol (IP) connection to an acquisition router.

7. The smart electricity meter according to claim 6, further comprising a command receiver, wherein
the command receiver is configured to receive a command for acquiring the information, the command for acquiring the information being sent by a system in a metering data collection and management system, a power distribution automation management system, an outage management system or the electricity consumption information acquisition master station system.

8. The smart electricity meter according to claim 6, further comprising a timer, wherein
the timer is configured to set a time at which the information is actively reported by the smart electricity meter, and when preset time for actively reporting the information is reached, send an information sending command to the information data sender.

9. An acquisition router, comprising a receiver, a routing Internet Protocol version 6 (IPv6) address device and a sender, wherein
the receiver is configured to receive a Transmission Control Protocol (TCP)/Internet Protocol (IP) connection initiated by a smart electricity meter;
the routing IPv6 address device is configured to store routing IPv6 addresses, and search for the routing IPv6 addresses with same rules as rules of an IPv6 address according to the IPv6 address; and
the sender is configured to send information to destination addresses specified by the information through the searched out routing IPv6 addresses.

10. The acquisition router according to claim 9, further comprising a prioritizing device, wherein
the prioritizing device is configured to determine, when the acquisition router simultaneously receives a plurality of TCP/IP connections initiated by the smart electricity meter, priorities of a plurality of pieces of information according to Quality of Service (QOS) rules; and
for each of the plurality of pieces of information, the prioritizing device is configured to control the acquisition router to search for the routing IPv6 addresses with the same rules as the rules of the IPv6 address corresponding to the piece of information in sequence according to the priority of the piece of information; and
the prioritizing device is configured to control the acquisition router to send the piece of information to destination addresses specified by the piece of information through the searched out routing IPv6 addresses according to the priority of the piece of information.
